(19) United States
(12) Patent Application Publication
(10) Pub. No.: US 2026/0013383 A1
(43) Pub. Date: Jan. 8, 2026

(54) Display Module, Heat Dissipation Film and Display Apparatus

(71) Applicants: CHENGDU BOE OPTOELECTRONICS TECHNOLOGY CO., LTD., Chengdu, Sichuan (CN); BOE TECHNOLOGY GROUP CO., LTD., Chaoyang District, Beijing (CN)

(72) Inventors: Jinglei Wang, Beijing (CN); Li Zeng, Beijing (CN); Xu Fan, Beijing (CN); Yang Yang, Beijing (CN); Linhuan Yan, Beijing (CN); Yang Shu, Beijing (CN)

(21) Appl. No.: 18/833,203

(22) PCT Filed: Sep. 12, 2023
(86) PCT No.: PCT/CN2023/118342

§ 371 Date: Jul. 25, 2024

(51) Int. Cl. H10K 59/80; H10K 102/00

(52) U.S. Cl. CPC H10K 59/8794; H10K 2102/311

(57) ABSTRACT

A display module includes a display panel and a heat dissipation film. The display panel includes a display portion which includes a display area and a peripheral area. The heat dissipation film is stacked on a non-display surface of the display portion. The heat dissipation film includes a metal layer and a composite film layer, and the metal layer is farther away from the display portion than the composite film layer. The composite film layer includes a first film layer structure and a filling portion that are connected to the metal layer. An orthographic projection of the first film layer structure on the display portion at least covers the display area, an orthographic projection of the filling portion on the display portion at least covers part of the peripheral area, and a thermal conductivity of the filling portion is greater than a thermal conductivity of the first film layer structure.

### CROSS-REFERENCE TO RELATED APPLICATION

This application is the United States national phase of International Patent Application No. PCT/CN2023/118342, filed Sep. 12, 2023, the disclosure of which is hereby incorporated by reference in its entirety.

### BACKGROUND OF THE INVENTION

### Field of the Invention

The present disclosure relates to the field of display technologies, and in particular, to a display module, a heat dissipation film and a display apparatus.

### Description of Related Art

With the continuous development of display technologies, display apparatuses have gradually been throughout people's lives. Organic light-emitting diode (OLED) display panels are widely used in smart products such as mobile phones, televisions and notebook computers due to self-luminescence, low power consumption, wide viewing angle, fast response speed, high contrast, and other advantages. Narrow frames are currently an important development direction for display apparatuses.

### SUMMARY OF THE INVENTION

In an aspect, a display module is provided. The display module includes a display panel and a heat dissipation film. The display panel includes a display portion for displaying an image. The display portion includes a display area and a peripheral area surrounding the display area. The heat dissipation film is stacked on a non-display surface of the display portion. The heat dissipation film includes a metal layer and a composite film layer that are stacked, and the metal layer is farther away from the display portion than the composite film layer. The composite film layer includes a first film layer structure and a filling portion, and the first film layer structure and the filling portion are both connected to the metal layer.

An orthographic projection of the first film layer structure on the display portion at least covers the display area, an orthographic projection of the filling portion on the display portion at least covers part of the peripheral area, and a thermal conductivity of the filling portion is greater than a thermal conductivity of the first film layer structure.

In some embodiments, the first film layer structure includes a bonding layer and a foam layer that are stacked, and the foam layer is closer to the metal layer than the bonding layer. A material of the filling portion includes at least one of thermally conductive silicone or graphite.

In some embodiments, the filling portion includes a thermally conductive silicone layer and a graphite layer. The thermally conductive silicone layer and the graphite layer are stacked in a direction perpendicular to the non-display surface of the display portion, or the thermally conductive silicone layer and the graphite layer are arranged side by side on a plane parallel to the non-display surface of the display portion and are connected to each other.

In some embodiments, a surface of the filling portion away from the metal layer has a serrated and/or wavy morphology.

In some embodiments, an edge of the first film layer structure has a notch, and the filling portion is disposed in the notch and connected to a side face of the first film layer structure at the notch.

In some embodiments, a side face of the first film structure outside the notch and a side face of the filling portion away from the display area are smoothly transitioned.

In some embodiments, the composite film layer has a rectangular structure, and the filling portion is at least disposed at a corner of the composite film layer.

In some embodiments, the display panel further includes a bending portion and a bonding portion that are disposed on at least one side of the display portion, and the display portion, the bending portion and the bonding portion are sequentially connected. The filling portion is disposed at two corners at both ends of a side edge of the composite film layer corresponding to the bending portion and the bonding portion.

In some embodiments, the orthographic projection of the filling portion on the display portion is substantially in an arc shape.

In some embodiments, the display portion includes a plurality of pixel units disposed in the display area, and a gate driver circuit and a connecting line that are disposed in the peripheral area. The connecting line is located between the gate driver circuit and the display area, and is used to connect the gate driver circuit and the plurality of pixel units. The orthographic projection of the filling portion on the display portion covers at least part of the gate driver circuit.

In some embodiments, the orthographic projection of the filling portion on the display portion covers at least part of the connecting line, or has no overlap with the connecting line.

In some embodiments, the display portion further includes an electrostatic protection circuit disposed in the peripheral area. The orthographic projection of the filling portion on the display portion at least covers part of the electrostatic protection circuit.

In some embodiments, the orthographic projection of the filling portion on the display portion and the display area have a gap therebetween.

In some embodiments, a distance between an edge of the orthographic projection of the filling portion on the display portion away from the display area and an edge of the display portion is in a range of 0 mm to 0.35 mm, inclusive.

In another aspect, a heat dissipation film is provided. The heat dissipation film includes a metal layer and a composite film layer. The composite film layer is stacked on the metal layer. The composite film layer includes a first film layer structure and a filling portion, and the first film layer structure and the filling portion are both connected to the metal layer. A thermal conductivity of the filling portion is greater than a thermal conductivity of the first film layer structure.

In some embodiments, the first film layer structure includes a bonding layer and a foam layer that are stacked, and the foam layer is closer to the metal layer than the bonding layer. A material of the filling portion includes at least one of thermally conductive silicone or graphite.

In some embodiments, an edge of the first film layer structure has a notch, and the filling portion is disposed in the notch and connected to a side face of the first film layer structure at the notch.

In some embodiments, the composite film layer has a rectangular structure, and the filling portion is at least disposed at a corner of the composite film layer. An orthographic projection of the filling portion on the metal layer is substantially in an arc shape.

In some embodiments, a surface of the filling portion away from the metal layer has a serrated and/or wavy morphology.

In another aspect, a display apparatus is provided. The display apparatus includes the display module as described in any of the above embodiments and a back film. The display panel in the display module includes the display portion, a bending portion and a bonding portion that are connected in sequence. The bonding portion is disposed on a side of the non-display surface of the display portion by bending action of the bending portion. The heat dissipation film in the display module is disposed between the display portion and the bonding portion.

The back film includes a first portion and a second portion. The first portion of the back film is disposed on the non-display surface of the display portion, and is closer to the display portion than the heat dissipation film. The second portion of the back film is disposed on a side of the bonding portion proximate to the display portion, and is closer to the display portion than the bonding portion.

### BRIEF DESCRIPTION OF THE DRAWINGS

In order to describe technical solutions in the present disclosure more clearly, accompanying drawings to be used in some embodiments of the present disclosure will be introduced briefly below. Obviously, the accompanying drawings to be described below are merely accompanying drawings of some embodiments of the present disclosure, and a person of ordinary skill in the art may obtain other drawings according to these drawings. In addition, the accompanying drawings to be described below may be regarded as schematic diagrams, but are not limitations on an actual size of a product, an actual process of a method and an actual timing of a signal to which the embodiments of the present disclosure relate.

FIG. 1 is a structural diagram of a display apparatus, in accordance with some embodiments;

FIG. 2 is a sectional view of the display apparatus in FIG. 1 taken along a section line DD;

FIG. 3 is a structural diagram of a display portion and a heat dissipation film, in accordance with some embodiments;

FIG. 4 is a structural diagram of a corner of a display portion, in accordance with some embodiments;

FIG. 5 is a structural diagram of a display portion and a heat dissipation film in the related art;

FIG. 6 is a sectional view of the heat dissipation film in FIG. 5 taken along a section line BB;

FIG. 7A is a sectional view of the heat dissipation film in FIG. 3 taken along a section line CC;

FIG. 7B is another sectional view of the heat dissipation film in FIG. 3 taken along a section line CC;

FIG. 7C is yet another sectional view of the heat dissipation film in FIG. 3 taken along a section line CC;

FIG. 7D is yet another sectional view of the heat dissipation film in FIG. 3 taken along a section line CC;

FIG. 8 is a structural diagram of a filling portion, in accordance with some embodiments;

FIG. 9 is a structural diagram of another filling portion, in accordance with some embodiments;

FIG. 10 is a structural diagram of yet another filling portion, in accordance with some embodiments;

FIG. 11 is a structural diagram of yet another filling portion, in accordance with some embodiments;

FIG. 12 is a structural diagram of yet another filling portion, in accordance with some embodiments;

FIG. 13A is a structural diagram of a first film structure, in accordance with some embodiments;

FIG. 13B is a structural diagram of a composite film layer, in accordance with some embodiments;

FIG. 14 is a structural diagram of a peripheral area and a filling portion, in accordance with some embodiments;

FIG. 15 is a structural diagram of another peripheral area and another filling portion, in accordance with some embodiments;

FIG. 16 is a structural diagram of yet another peripheral area and yet another filling portion, in accordance with some embodiments;

FIG. 17 is a structural diagram of a first film structure and a filling portion, in accordance with some embodiments;

FIG. 18 is a structural diagram of another first film structure and another filling portion, in accordance with some embodiments;

FIG. 19 is a structural diagram of yet another first film structure and yet another filling portion, in accordance with some embodiments; and

FIG. 20 is a structural diagram of yet another first film structure and yet another filling portion, in accordance with some embodiments.

### DESCRIPTION OF THE INVENTION

Technical solutions in some embodiments of the present disclosure will be described clearly and completely with reference to the accompanying drawings below. Obviously, the described embodiments are merely some but not all embodiments of the present disclosure. All other embodiments obtained by a person of ordinary skill in the art based on the embodiments of the present disclosure shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive, i.e., “including, but not limited to”. In the description of the specification, the terms such as “one embodiment”, “some embodiments”, “exemplary embodiments”, “example”, “specific example” or “some examples” are intended to indicate that specific features, structures, materials or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics described herein may be included in any one or more embodiments or examples in any suitable manner.

Hereinafter, the terms such as “first” and “second” are used for descriptive purposes only, and are not to be construed as indicating or implying the relative importance or implicitly indicating the number of indicated technical features. Thus, features defined with “first” or “second” may explicitly or implicitly include one or more of the features. In the description of the embodiments of the present disclosure, the term “a plurality of” or “the plurality of” means two or more unless otherwise specified.

In the description of some embodiments, the expressions “coupled” and “connected” and derivatives thereof may be used. The term “connection” should be understood in a broad sense. For example, the “connection” may be a fixed connection, a detachable connection, or of an integrated structure; it may be a direct connection or an indirect connection by an intermediate medium. The term “coupled” indicates, for example, that two or more components are in direct physical or electrical contact. However, the term “coupled” or “communicatively coupled” may also mean that two or more components are not in direct contact with each other, but still cooperate or interact with each other. The embodiments disclosed herein are not necessarily limited to the content herein.

The phrase “at least one of A, B and C” has a same meaning as the phrase “at least one of A, B or C”, and they both include the following combinations of A, B and C: only A, only B, only C, a combination of A and B, a combination of A and C, a combination of B and C, and a combination of A, B and C.

The phrase “A and/or B” includes the following three combinations: only A, only B, and a combination of A and B.

The term “about”, “substantially” or “approximately” as used herein includes a stated value and an average value within an acceptable range of deviation of a particular value. The acceptable range of deviation is determined by a person of ordinary skill in the art in consideration of the measurement in question and errors associated with the measurement of a particular quantity (i.e., limitations of the measurement system).

The term such as “parallel”, “perpendicular” or “equal” as used herein includes a stated condition and a condition similar to the stated condition. A range of the similar condition is within an acceptable range of deviation. The acceptable range of deviation is determined by a person of ordinary skill in the art in view of measurement in question and errors associated with the measurement of a particular quantity (i.e., limitations of the measurement system). For example, the term “parallel” includes absolute parallelism and approximate parallelism, and an acceptable range of deviation of the approximate parallelism may be a deviation within 5°; the term “perpendicular” includes absolute perpendicularity and approximate perpendicularity, and an acceptable range of deviation of the approximate perpendicularity may also be a deviation within 5°; and the term “equal” includes absolute equality and approximate equality, and an acceptable range of deviation of the approximate equality may be a difference between two equals being less than or equal to 5% of either of the two equals.

It will be understood that when a layer or element is referred to as being on another layer or substrate, the layer or element may be directly on the another layer or substrate, or there may be intermediate layer(s) between the layer or element and the another layer or substrate.

Exemplary embodiments are described herein with reference to sectional views and/or plan views as idealized exemplary drawings. In the accompanying drawings, thicknesses of layers and sizes of areas/regions are enlarged for clarity. Variations in shapes relative to the accompanying drawings due to, for example, manufacturing technologies and/or tolerances may be envisaged. Therefore, the exemplary embodiments should not be construed to be limited to the shapes of areas/regions shown herein, but to include deviations in the shapes due to, for example, manufacturing. For example, an etched area/region shown in a rectangular shape generally has a feature of being curved. Therefore, the areas/regions shown in the accompanying drawings are schematic in nature, and their shapes are not intended to show actual shapes of the areas/regions in an apparatus, and are not intended to limit the scope of the exemplary embodiments.

It will be noted that, the mark such as 202/20 appearing in the drawings of the present disclosure indicates that a component 202 belongs to a component 20, and other similar marks appearing in the drawings also follow the above description.

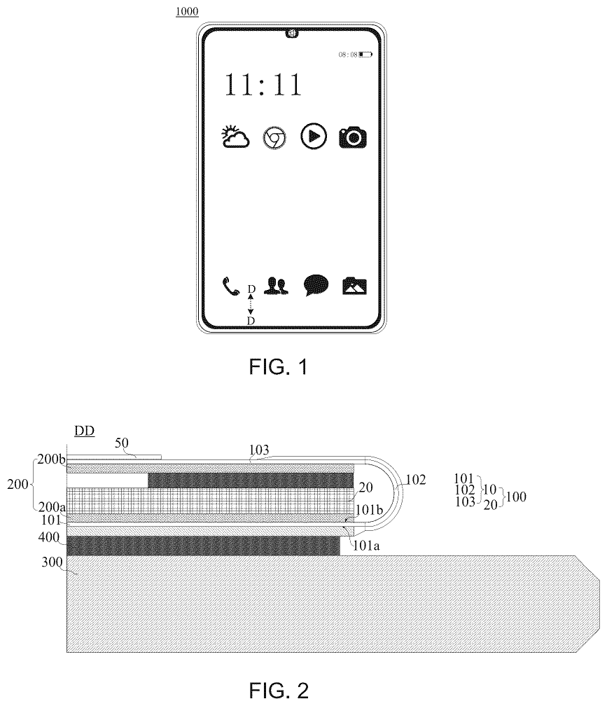

As shown in FIG. 1, some embodiments of the present disclosure provide a display apparatus 1000. The display apparatus 1000 may be any product or component having a display function, such as a television, a display, a notebook computer, a tablet computer, a mobile phone or a navigator. FIG. 1 illustrates an example where the display apparatus 1000 is a mobile phone.

For example, the display apparatus 1000 may be any device that displays images whether in motion (e.g., videos) or stationary (e.g., static images), and regardless of text or image. More specifically, it is expected that the embodiments may be implemented in or associated with a variety of electronic devices. The variety of electronic devices may include (but are not limited to), for example, mobile phones, wireless devices, personal digital assistants (PDAs), hand-held or portable computers, global positioning system (GPS) receivers/navigators, cameras, MPEG-4 Part 14 (MP4) video players, video cameras, game consoles, watches, clocks, calculators, TV monitors, flat-panel displays, computer monitors, car displays (e.g., odometer displays), navigators, cockpit controllers and/or displays, camera view displays (e.g., display of rear view camera in vehicles), electronic photos, electronic billboards or signs, projectors, architectural structures, packaging and aesthetic structures (e.g., displays for displaying an image of a piece of jewelry).

For example, the display apparatus 1000 may be a liquid crystal display (LCD); alternatively, the display apparatus 100 may be an electroluminescent display apparatus or a photoluminescent display apparatus. In a case where the display apparatus is the electroluminescent display apparatus, the electroluminescent display apparatus may be an organic light-emitting diode (OLED) display apparatus or a quantum dot light-emitting diode (QLED) display apparatus. In a case where the display apparatus is the photoluminescent display apparatus, the photoluminescent display apparatus may be a quantum dot photoluminescent display apparatus.

FIG. 2 is a sectional view of the display apparatus 1000 in FIG. 1 taken along a section line DD. As shown in FIG. 2, the display apparatus 1000 includes a display module 100 and a back film 200. The display module 100 includes a display panel 10. The display panel 10 includes a display portion 101, a bending portion 102, and a bonding portion 103 that are sequentially connected.

It will be noted that the display portion 101 is configured to display images. The display portion 101 has a display surface 101a and a non-display surface 101b. The display surface 101a of the display portion 101 refers to a surface of the display portion 101 for displaying images, and the non-display surface 101b of the display portion 101 refers to a surface of the display portion 101 facing away from the display surface 101a.

The bending portion 102 is bendable, and the bonding portion 103 is disposed on the non-display surface 101b of the display portion 101 due to the bending action of the bending portion 102. In order to achieve the bending of the bending portion 102 of the display panel 10, the display panel 10 in the embodiments may be a flexible display panel, which is made of a flexible material. The selected flexible material may be made of polymer materials such as polyethylene terephthalate, polyarylethersulfone, polyethylene naphthalate, or polyimide. It will be noted that the material of the flexible display panel is not limited specifically in the present disclosure. No matter which material (including all flexible materials that can be used in a flexible substrate in the prior art) is selected, it needs to have a certain degree of stretchability to form a flexible display substrate. During specific manufacturing, it is necessary to select the flexible material that meets the stretchability requirements depending on the actual needs of the display panel 10.

For example, the bending of the display panel 10 may be that the bending portion 102 is bent, while the display portion 101 and the bonding portion 103 that are located on both sides of the bending portion 102 are not bent. Alternatively, the bending of the display panel 10 may be that the bending portion 102 is bent greatly, and a part of the display portion 101 proximate to an edge of the bending portion 102 may be slightly bent, so as to form a curved display apparatus.

As shown in FIG. 2, the bonding portion 103 may include a driver chip 50. The driver chip 50 may include, for example, a source driver chip for outputting display signals to data display. The driver chip 50 may be mounted onto a surface of the bonding portion 103 away from the display portion 101 through a bonding process, so as to achieve a narrow frame design of the display portion 101.

With continued reference to FIG. 2, the back film 200 includes a first portion 200a and a second portion 200b. The first portion 200a of the back film 200 is disposed on the non-display surface of the display portion 101, and the second portion 200b of the back film 200 is disposed on a side of the bonding portion 103 proximate to the display portion 101 and closer to the display portion 101 than the bonding portion 103.

By providing the back film 200, when the display panel 10 is bent due to the bending action of the bending portion 102 so that the bonding portion 103 is disposed on the non-display surface 101b of the display portion 101, the back film 200 may provide support to the display portion 101 and the bonding portion 103 of the display panel 10, so as to achieve a good bending effect.

For example, a material of the back film 200 is polyethylene terephthalate (PET), polyimide (PI), or cyclo olefin polymer (COP).

For example, the display panel 10 and the back film 200 may be bonded to each other by optically clear adhesive (OCA), thereby being beneficial to ensuring the light transmittance property of the display panel 10.

In some embodiments, as shown in FIG. 2, the display apparatus 1000 may further include a cover plate 300 and an adhesive layer 400. The cover plate 300 is disposed on the display surface 101a of the display portion 101 of the display panel 10, and the adhesive layer 400 is disposed on a side of the cover plate 300 proximate to the display panel 10 and is used for bonding the cover plate 300 to the display panel 10.

The cover plate 300 may separate the display panel 10 from the external environment and provide protection for the display panel 10.

For example, the cover plate 300 is a single-layer cover plate, or a multi-layer cover plate 300 laminated together by adhesive material.

For example, the cover plate 300 is a silicate glass cover plate, which may be a curved glass or an ultra-thin glass. Alternatively, the cover plate 300 is a flexible polymer film cover plate, which may be a transparent polyimide or PET or polyurethane. Alternatively, the cover plate 300 may be a combination of the above several polymer films, or a combination of a polymer film and glass.

In some embodiments, the display apparatus 1000 may further include an under-screen camera and an under-screen fingerprint recognition sensor, so that the display apparatus 1000 may realize various functions such as photographing, video recording, fingerprint recognition or face recognition, which is not limited, and adaptive design may be made depending on actual needs.

A structure of the display module 100 will be described in detail below.

As shown in FIG. 2, the display module 100 includes the display panel 10.

For example, the display portion 101 of the display panel 10 is of a rectangular structure, a circular structure, or other shapes with corners, which is not specifically limited in the present disclosure.

It will be noted that, the “rectangular structure” means that a shape of an edge of the display portion 101 is a rectangle as a whole, but is not limited to a standard rectangle. That is, the “rectangle” here includes not only a standard rectangle but also a shape similar to the rectangle in consideration of process conditions. For example, long sides and short sides of the rectangle are curved at each intersecting position (i.e., each corner), that is, the corners are smooth, so that the edge of the display portion 101 is in a shape of a round-corner rectangle in a plan view.

Some embodiments of the present disclosure are exemplarily illustrated by taking an example where the display portion 101 has a rectangular structure in the following embodiments, but the implementations of the present disclosure include but are not limited thereto. The shape of the display portion 101 may also consider any other shape with corners.

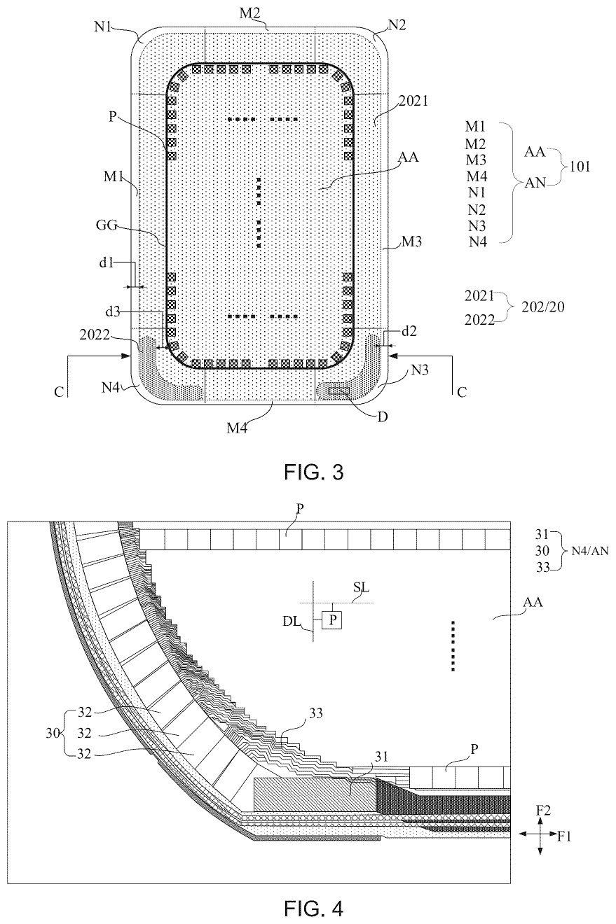

In some embodiments, as shown in FIG. 3, the display portion 101 of the display panel 10 includes a display area AA. Since the display portion 101 has a rectangular structure, and the display area AA also has a rectangular structure accordingly.

It will be noted that the display area AA of the display portion 101 of the display panel 10 is used to display images.

In order to realize the image display function of the display panel 10, display devices are formed in the display area AA of the display portion 101. For example, the display devices are organic light-emitting diode (OLED) devices or liquid crystal display devices, and the selection may be made depending on actual needs of the user.

For example, in a case where the display panel is an OLED display panel, the OLED display panel includes an array substrate and a pixel defining layer located on the array substrate. An anode, a hole injection layer, a hole transport layer, a light-emitting layer, an electron transport layer, an electron injection layer and a cathode are sequentially provided in a pixel defining area of the pixel defining layer.

In a case where the display device is a LCD device, the LCD device includes an array substrate and a color film substrate that are disposed oppositely, and a liquid crystal layer disposed between the array substrate and the color film substrate.

Some embodiments of the present disclosure are exemplarily illustrated by taking an example where the display panel 10 is an OLED display panel below, but the implementations of the present disclosure include but are not limited thereto, and any other display panel may also be considered as long as the same technical concept is applied.

In some embodiments, as shown in FIG. 4, the display area AA of the display portion 101 is provided therein with a plurality of pixel units P and wirings capable of applying electrical signals to the plurality of pixel units P. Each pixel unit P includes at least three sub-pixels, where the sub-pixel is the minimum light-emitting unit in the display area AA.

For example, the plurality of pixel units P are arranged in a plurality of rows and a plurality of columns.

In some examples, a plurality of sub-pixels emit light of the same color, and the display portion 101 may further include a color filter layer provided on a light exit side of the plurality of sub-pixels.

For example, the plurality of sub-pixels all emit white light, red light, green light, blue light or light of other color. In this case, the light emitted by the sub-pixels exits by maintaining light of the same color after passing through the color filter layer, or exits by being converted into light of other colors. Therefore, when the plurality of sub-pixels emit light of the same color, the display portion 101 can achieve multi-color light output.

In some other examples, the plurality of sub-pixels emit light of different colors. For example, the plurality of sub-pixels include a red sub-pixel for emitting red light, a green sub-pixel for emitting green light, and a blue sub-pixel for emitting blue light, thereby realizing multi-color light output of the display portion 101.

It will be noted that each pixel unit P includes at least three sub-pixels, that is, each pixel unit P may include three, four or more sub-pixels, and a plurality of sub-pixels included in each pixel unit P may be a row of sub-pixels, a column of sub-pixels or a group of sub-pixels, where the group of sub-pixels may be a plurality of adjacent sub-pixels, and the plurality of adjacent sub-pixels are arranged in a row, a column, an L shape, a rectangle or a rhombus.

Moreover, light-emitting areas of the plurality of sub-pixels included in each pixel unit P may be the same or not exactly the same. The above is only an exemplary description but not intended to limit the present disclosure, and adaptive design may be made depending on actual needs.

As shown in FIG. 4, the wirings capable of applying the electrical signals to the plurality of pixel units P may include a plurality of scan lines SL, a plurality of data lines DL, and the like. Each of the plurality of scan lines SL may extend in a first direction F1, and each of the plurality of data lines DL may extend in a second direction F2. The plurality of scan lines SL may be arranged, for example, in a plurality of rows to transmit scan signals to the pixel units P, and the plurality of data lines DL may be arranged, for example, in a plurality of columns to transmit data signals to the pixel units P. Each of the pixel units P may be connected to a corresponding scan line SL among the plurality of scan lines SL and a corresponding data line DL among the plurality of data lines DL.

In some embodiments, as shown in FIG. 3, the display portion 101 of the display panel 10 further includes a peripheral area AN surrounding the display area AA.

It will be noted that, FIG. 3 illustrates an example where the black bold solid line is as a boundary GG of the display area AA. The boundary GG of the display area AA may be formed by connecting edges, proximate to the peripheral area AN, of the outermost multiple pixel units P among the plurality of pixel units P in the display area AA. For example, edges, proximate to the peripheral area AN, of anodes of the outermost sub-pixels in the outermost multiple pixel units P may be connected together to form the boundary GG of the display area AA.

It will be noted that, FIG. 3 illustrates an example where the peripheral area AN of the display portion 101 completely surrounds the display area AA, but the provision manner of the peripheral area AN and the display area AA in the present disclosure is not limited thereto. For example, the peripheral area AN may partially surrounds the display area AA.

As shown in FIG. 3, since the display area AA has a rectangular structure, the peripheral area AN surrounding the display area AA has a rectangular ring structure accordingly. The peripheral area AN includes a first frame region M1 and a third frame region M3 that are disposed oppositely, and a second frame region M2 and a fourth frame region M4 that are disposed oppositely. A first corner region N1 is provided between the first frame region M1 and the second frame region M2, a second corner region N2 is provided between the second frame region M2 and the third frame region M3, a third corner region N3 is provided between the third frame region M3 and the fourth frame region M4, and a fourth corner region N4 is provided between the fourth frame region M4 and the first frame region M1. That is, the first corner region N1, the second corner region N2, the third corner region N3 and the fourth corner region N4 correspond to four corners of the peripheral area AN.

The peripheral area AN of the display portion 101 may be used to be provided with peripheral circuits and signal lines of the display area AA.

For example, the peripheral circuit may include a panel crack detect (PCD) circuit, a gate driver circuit, an electrostatic protection circuit, and the like. The panel crack detect circuit is used to detect whether there are cracks in the display panel extending from the boundary to the inside. The gate driver circuit is used to drive the pixel units P to display images. The electrostatic protection circuit (as shown by a mark 31 in FIG. 4) is used to conduct static electricity in signal lines in the display portion 101, so as to protect the signal lines in the display portion 101 from being damaged by static electricity. If the electrostatic protection circuit is not provided, it may be prone to causing problems such as flickering or greenish of the display portion 101.

As shown in FIG. 4, the gate driver circuit 30 includes a plurality of gate driver on array (GOA) circuits 32 that are cascaded. The plurality of GOA circuits 32 may include, for example, a scan driver circuit and/or an emission driver circuit. The scan driver circuit is used to provide one or more electrical signals such as scan signals (Scan signals) to the pixel units P along signal lines such as scan lines SL; and the emission driver circuit is used to provide one or more electrical signals such as emission control signals (EM signals) to the pixel units P along signal lines such as emission control lines.

The signal lines provided in the peripheral area AN may include signal lines required for operation of the pixel units P, a VSS line, and signal lines required for operation of the gate driver circuit 30.

The signal lines required for operation of the pixel units P include, for example, a direct current (DC) power line (a vinit line) and the like.

The VSS line is connected to cathodes of the pixel units P to provide the pixel units P with a cathode signal.

The signal lines required for operation of the gate driver circuit 30 include, for example, a clock signal line (CLK), a high voltage signal line (VGH), a low voltage signal line (VGL), an initial signal line (STV), and the like.

As shown in FIG. 4, the signal lines provided in the peripheral area AN further include connecting lines 33, and the connecting lines 33 are used to connect the plurality of GOA circuits 32 and the plurality of pixel units P. For example, a single GOA circuit 32 is electrically connected to a row of pixel units P by a connecting line 33, so as to provide a Scan signal or an EM signal to the row of pixel units P.

In some embodiments, as shown in FIG. 3, at least one region of the first frame region M1, the second frame region M2, the third frame region M3 and the fourth frame region M4 in the peripheral area AN is provided with one or more of the GOA circuits 32, the electrostatic protection circuit 31 and the connecting lines 33.

In some other embodiments, as shown in FIGS. 3 and 4, at least one region of the first corner region N1, the second corner region N2, the third corner region N3 and the fourth corner region N4 in the peripheral area AN is also provided with the GOA circuits 32, the electrostatic protection circuit 31 and the connecting lines 33.

FIG. 4 is a schematic diagram showing arrangement of the GOA circuits 32, the electrostatic protection circuit 31 and the connection lines 33 in the fourth corner region N4 in FIG. 3. If the first corner region N1, the second corner region N2 and the third corner region N3 in the peripheral area AN need to be provided with GOA circuits 32, an electrostatic protection circuit 31 and connecting lines 33, the provision manner thereof is the same as or similar to the provision manner of the GOA circuits 32, the electrostatic protection circuit 31 and the connecting lines 33 in the fourth corner region N4. Here, only the provision manner of the GOA circuits 32, the electrostatic protection circuit 31 and the connecting lines 33 in the fourth corner region N4 is illustrated.

In a case where the driving mode of the pixel units P in the display area AA in FIG. 4 is double-side driving, the third corner region N3 also needs to be provided with GOA circuits. The provision manner of the GOA circuits thereof is the same as or similar to the provision manner of the GOA circuits 32 in the fourth corner region N4, and details are not repeated here.

It can be understood that the connection lines 33 in FIG. 4 extends linearly in a “Z” shape; alternatively, the connection line 33 may extend linearly or in a curved shape. The specific shape of the connection line 33 is not limited in the embodiments of the present disclosure.

The electrostatic protection circuit 31 may be disposed at a side of the fourth corner region N4 proximate to the fourth frame region M4.

As shown in FIG. 2, the display module 100 further includes a heat dissipation film 20. The heat dissipation film 20 is stacked on the non-display surface 101b of the display portion 101 of the display panel 10 and is disposed between the display portion 101 and the bonding portion 103. Thus, it may play a role of dissipating heat and shielding light.

In some embodiments, as shown in FIG. 2, the first portion 200a of the back film 200 is closer to the display portion 101 than the heat dissipation film 20.

FIG. 3 is a structural diagram of a display portion 101 and a heat dissipation film 20 of the display panel 10 in accordance with some embodiments. In order to facilitate explanation of the stacking relationship between the display portion 101 and the heat dissipation film 20, transparency treatment is applied to the display portion 101 to expose the heat dissipation film 20 disposed on the non-display surface 101b of the display portion 101. For convenience of distinguishing the display portion 101 and the heat dissipation film 20, a region surrounded by the outermost solid line in FIG. 3 is the display portion 101 of the display panel 10, and a region surrounded by the dotted line is the heat dissipation film 20.

For example, with continued reference to FIG. 3, a distance d1 between an orthographic projection of an edge of the heat dissipation film 20 on the display portion 101 and an edge of the display portion 101 is in a range of 0 mm to 0.35 mm, inclusive. That is, the orthographic projection of the edge of the heat dissipation film 20 on the display portion 101 may coincide with or substantially coincide with the edge of the display portion 101, i.e., the shapes of the heat dissipation film 20 and the display portion 101 may be the same or substantially the same, and the plane areas of the heat dissipation film 20 and the display portion 101 may be the same or substantially the same. For example, the orthographic projection of the edge of the heat dissipation film 20 on the display portion 101 may be within the edge of the display portion 101, and the maximum value of the distance d1 between the orthographic projection of the edge of the heat dissipation film 20 on the display portion 101 and the edge of the display portion 101 is 0.35 mm, that is, the plane area of the heat dissipation film 20 may be smaller than that of the display portion 101.

For example, the distance d1 between the orthographic projection of the edge of the heat dissipation film 20 on the display portion 101 and the edge of the display portion 101 is 0 mm, 0.06 mm, 0.12 mm, 0.18 mm, 0.26 mm, 0.30 mm, or 0.35 mm.

FIG. 3 illustrates an example where each position of the orthographic projection of the edge of the heat dissipation film 20 on the display portion 101 and the edge of the display portion 101 have the same or similar distance d1 therebetween. However, the provision manner of the distance d1 between each position of the orthographic projection of the edge of the heat dissipation film 20 on the display portion 101 and the edge of the display portion 101 in the present disclosure is not limited thereto. For example, various positions of the orthographic projection of the edge of the heat dissipation film 20 on the display portion 101 and the edge of the display portion 101 may have different distances d1 therebetween. For example, a part of the orthographic projection of the edge of the heat dissipation film 20 on the display portion 101 may coincide with or substantially coincide with the edge of the display portion 101, and the distance d1 between another part of the orthographic projection of the edge of the heat dissipation film 20 on the display portion 101 and the edge of the display portion 101 may be 0.26 mm, 0.30 mm or 0.35 mm.

It will be noted that in order to avoid light leakage from the display area AA of the display portion 101, the orthographic projection of the heat dissipation film 20 on the display portion 101 needs to completely cover the display area AA of the display portion 101.

For example, the heat dissipation film 20 may have a rectangular structure, a circular structure, or other shapes with corners, as long as the heat dissipation film 20 may dissipate heat from the display portion 101 and completely cover the display area AA of the display portion 101, and the present disclosure does not make any specific limitation on this.

On a basis of the display portion 101 having a rectangular structure, the heat dissipation film 20 may have a rectangular structure with the same or similar shape as the display portion 101. Some embodiments of the present disclosure are schematically described below by taking an example where the heat dissipation film 20 has a rectangular structure with the same or similar shape as the display portion 101, but the embodiments of the present disclosure include but are not limited thereto, and the shape of the heat dissipation film 20 may also consider any other shape with corners.

In some embodiments, a side of the heat dissipation film 20 proximate to the bending portion 102 and the bonding portion 103 of the display panel 10 may extend toward the bending portion 102 and the bonding portion 103 of the display panel 10, so as to facilitate heat dissipation of the bending portion 102 and the bonding portion 103 of the display panel 10.

Hereinafter, a structure of the heat dissipation film 20 will be described in detail below.

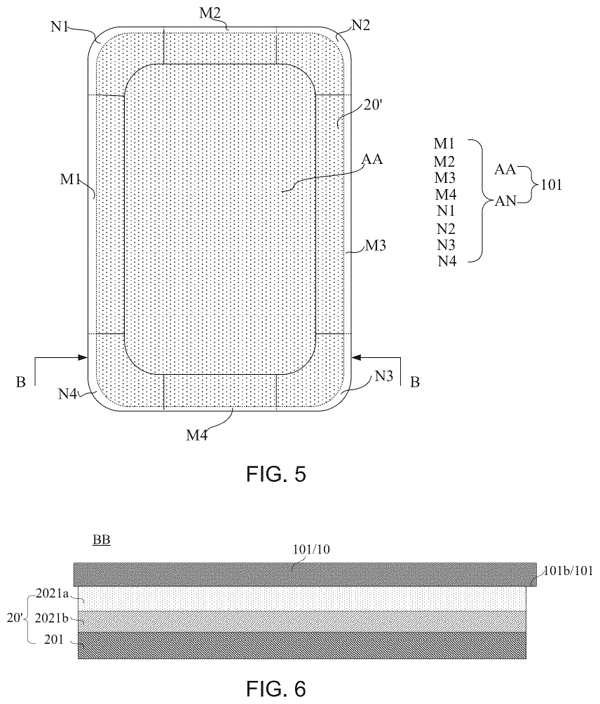

As shown in FIG. 5, FIG. 5 is a structural diagram of a display portion 101 and a heat dissipation film 20′ of a display panel 10 provided in the related art. In order to facilitate description of the stacking relationship between the display portion 101 and the heat dissipation film 20′, transparency treatment is applied to the display portion 101 to expose the heat dissipation film 20′ disposed on the non-display surface 101b of the display portion 101. For convenience of distinguishing the display portion 101 and the heat dissipation film 20′, a region surrounded by the outermost solid line in FIG. 5 is the display portion 101 of the display panel 10, and a region surrounded by the dotted line is the heat dissipation film 20′.

FIG. 6 is a sectional view of the display portion 101 and the heat dissipation film 20′ in FIG. 5 taken along the section line BB. As shown in FIG. 6, the heat dissipation film 20′ includes a metal layer 201, a foam layer 2021b and a bonding layer 2021a that are stacked in sequence. The bonding layer 2021a is connected to the non-display surface 101b of the display portion 101.

The narrow frame is an important development direction of the display panel 10 currently. With continuous narrowing of the frame of the display panel 10, an area of the peripheral area AN of the display portion 101 gradually decreases, and a region, in the peripheral area AN, where the peripheral circuits (such as the gate driver circuit, the electrostatic protection circuit, and the PCD circuit), the signal lines (such as the vinit line and the VSS line), and the connecting lines for connecting the gate driver circuit and the pixel units are provided is continuously reduced. Under a condition of high brightness of the display panel 10, the heat generated in the peripheral area AN increases, which makes it difficult to dissipate the heat generated in the peripheral area AN, resulting in heat accumulation in the peripheral area AN and temperature increase, and further leading to reduction of lives of light-emitting devices in the display area AA adjacent to the peripheral area AN. As a result, the image in the display area AA displays unevenly, thereby affecting the display effect.

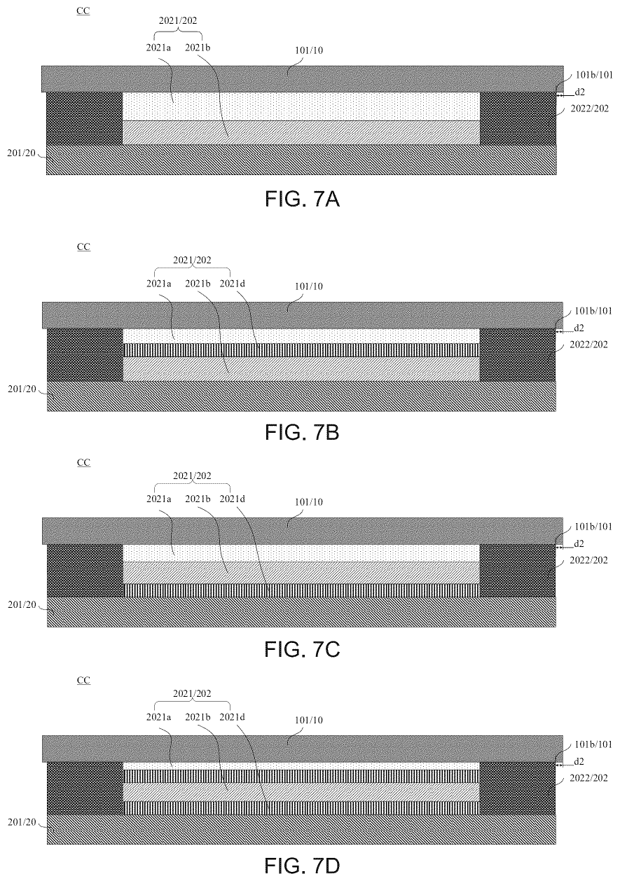

Based on this, as shown in FIGS. 7A to 7D, FIGS. 7A to 7D are each a sectional view of the display portion 101 and the heat dissipation film 20 in FIG. 3 taken along the section line CC. The heat dissipation film 20 includes a metal layer 201 and a composite film layer 202 that are stacked. The metal layer 201 is farther away from the display portion 101 than the composite film layer 202. The composite film layer 202 includes a first film layer structure 2021 and a filling portion 2022, and both the first film layer structure 2021 and the filling portion 2022 are connected to the metal layer 201.

An orthographic projection of the first film layer structure 2021 on the display portion 101 at least covers the display area AA, and an orthographic projection of the filling portion 2022 on the display portion 101 at least covers part of the peripheral area AN. The thermal conductivity of the filling portion 2022 is greater than the thermal conductivity of the first film layer structure 2021.

The first film layer structure 2021 and the filling portion 2022 are provided, the thermal conductivity of the filling portion 2022 is greater than the thermal conductivity of the first film layer structure 2021, and the orthographic projection of the filling portion 2022 on the display portion 101 covers at least part of the peripheral area AN. In this way, the heat generated by the circuits in the peripheral area AN may be conducted to the metal layer 201 by the filling portion 2022 and dissipated outwards by the metal layer 201. This is beneficial to improving the heat dissipation efficiency of the peripheral area AN, and display abnormalities of the display panel 10 due to poor heat dissipation may be avoided as much as possible.

For example, FIGS. 7A to 7D illustrate examples where an edge of an orthographic projection of the metal layer 201 on a plane where the composite film layer 202 is located coincides with or approximately coincides with an edge of the composite film layer 202. However, in the present disclosure, the positional relationship between the edge of the orthographic projection of the metal layer 201 on the plane where the composite film layer 202 is located and the edge of the composite film layer 202 is not limited thereto. For example, at least part of the edge of the orthographic projection of the metal layer 201 on the plane where the composite film layer 202 is located is provided on an inner side of the edge of the composite film layer 202. That is, the metal layer 201 is designed to be retracted relative to the composite film layer 202.

Since the heat dissipation film 20 has a stacked structure, during manufacturing the heat dissipation film 20, all layers are generally bonded over a large area and then cut to obtain the heat dissipation film 20 for bonding to the display panel 10. During cutting, advance and retreat of the cutter will affect the bonding effect of the edge of the heat dissipation film 20 (i.e., separation phenomenon occurs in some layers at the edge of the heat dissipation film 20). By designing the metal layer 201 to be retracted relative to the composite film layer 202, the influence of advance and retreat of the cutter on the bonding effect of the edge of the heat dissipation film 20 may be reduced during cutting, thereby improving the yield of the heat dissipation film 20.

In some embodiments, the metal layer 201 may be made of copper or aluminum, and may play a role of electromagnetic shielding and heat dissipation.

In some embodiments, as shown in FIG. 7A, the first film layer structure 2021 includes a bonding layer 2021a and a foam layer 2021b that are stacked, and the foam layer 2021b is closer to the metal layer 201 than the bonding layer 2021a.

The provision of the foam layer 2021b may buffer the external force and reduce the damage to the display panel 10 caused by the bonding pressure during bonding the heat dissipation film 20 to the display panel 10.

For example, the bonding layer 2021a may be a grid adhesive layer. Therefore, it may not only apply pressure through the grid to imprint vertical and horizontal grids on the adhesive surface, thereby preventing curling caused by shrinkage of the adhesive layer and enhancing tightness of attachment of the foam layer 2021b and the display panel 10, but also avoid generation of bubbles, bulging and other undesirable phenomena when the foam layer 2021b is attached to the display portion 101 of the display panel 10.

In some other embodiments, as shown in FIGS. 7B to 7D, the first film layer structure 2021 further includes support layer(s) 2021d, which is beneficial to further improving the overall strength of the first film layer structure 2021, reducing the probability of deformation of the first film layer structure 2021, and further reducing the probability of deformation of a region of the display portion 101 of the display panel 10 corresponding to the first film layer structure 2021 due to the deformation of the first film layer structure 2021, thereby improving the poor molding of the display panel 10.

For example, as shown in FIG. 7B, the support layer 2021d may be provided between the bonding layer 2021a and the foam layer 2021b.

As another example, as shown in FIG. 7C, the support layer 2021d may be provided between the foam layer 2021b and the metal layer 201.

As another example, as shown in FIG. 7D, the support layers 2021d may be provided between the bonding layer 2021a and the foam layer 2021b, and between the foam layer 2021b and the metal layer 201.

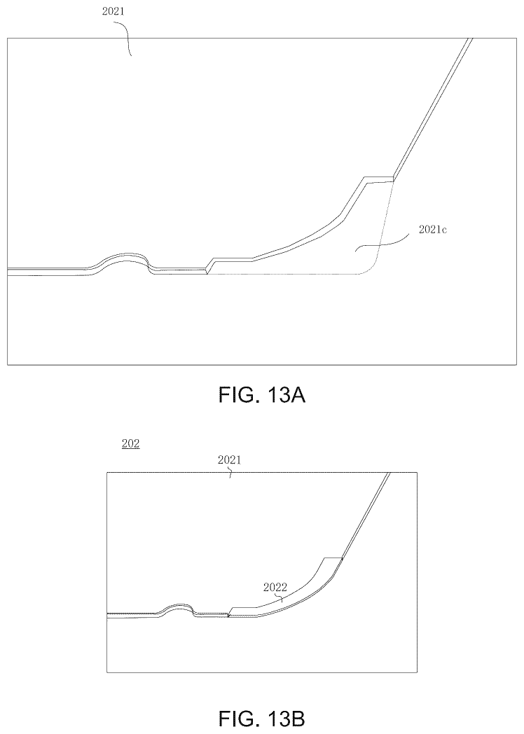

In some embodiments, as shown in FIG. 13A, an edge of the first film layer structure 2021 has a notch 2021c.

For example, an orthographic projection of the notch 2021c on the metal layer 201 may be in a shape of a circle, an arc, a sector, a polygon, or the like. In specific application scenarios, simulation may be performed according to actual needs to obtain an optimal shape, and targeted settings may be made based on this.

For example, the method for forming the notch 2021c in the first film layer structure 2021 may be to cut the first film layer structure 2021, so as to remove a portion of the first film layer structure 2021 to obtain the notch 2021c.

As shown in FIG. 13B, the filling portion 2022 is disposed in the notch 2021c and is connected to a side face of the first film layer structure 2021 at the notch 2021c. The side face of the first film layer structure 2021 outside the notch 2021c and a side face of the filling portion 2022 away from the display area AA are smoothly transitioned. That is, the filling portion 2022 and the notch 2021c have the same shapes and substantially the same sizes, so that the filling portion 2022 fills the notch 2021c.

For example, in a case where the shape of the orthographic projection of the notch 2021c on the metal layer 201 is one of a circle, an arc, a sector and a polygon, the shape of the filling portion 2022 is also one of a circle, an arc, a sector and a polygon that is adapted to the shape of the notch 2021c.

For example, the method for forming the filling portion 2022 may be to profile a portion of the first film layer structure 2021 removed when the first film layer structure 2021 is cut to obtain the notch 2021c, so as to obtain the filling portion 2022 adapted to the notch 2021c.

Since there may be errors during forming the filling portion 2022, a surface of the filling portion 2022 away from the metal layer 201 and a surface of the first film layer structure 2021 away from the metal layer 201 are caused not to be in the same plane. For example, the surface of the filling portion 2022 away from the metal layer 201 is closer to or farther away from the display portion 101 than the surface of the first film layer structure 2021 away from the metal layer 201.

In a case where the surface of the filling portion 2022 away from the metal layer 201 is closer to the display portion 101 than the surface of the first film layer structure 2021 away from the metal layer 201, the display devices in the display area AA may be damaged.

Based on this, as shown in FIG. 3, in order to avoid damage to the display devices, there is a distance d3 between the orthographic projection of the filling portion 2022 on the display portion 101 and the edge of the display area AA. That is, the orthographic projection of the filling portion 2022 on the display portion 101 does not overlap with the display area AA, and the orthographic projection of the edge of the filling portion 2022 on the display portion 101 does not coincide with the edge of the display area AA.

In some embodiments, with continued reference to FIG. 3, with an edge of the filling portion 2022 on a side thereof away from the display area AA as an outer edge of the filling portion 2022, a distance d2 between the orthographic projection of the outer edge of the filling portion 2022 on the display portion 101 and the edge of the display portion 101 is equal to the distance d1 between the orthographic projection of the edge of the heat dissipation film 20 on the display portion 101 and the edge of the display portion 101, and is also set to be in a range of 0 mm to 0.35 mm, inclusive.

For example, the distance d2 between the orthographic projection of the outer edge of the filling portion 2022 on the display portion 101 and the edge of the display portion 101 is 0 mm, 0.06 mm, 0.12 mm, 0.18 mm, 0.26 mm, 0.30 mm, or 0.35 mm.

In some embodiments, with continued reference to FIG. 3, the material of the filling portion 2022 includes at least one of thermally conductive silicone and graphite. The thermal conductivity of thermally conductive silicone and the thermal conductivity of graphite are both higher than that of foam, which is beneficial to improving the heat dissipation efficiency of the peripheral area AN of the display portion 101.

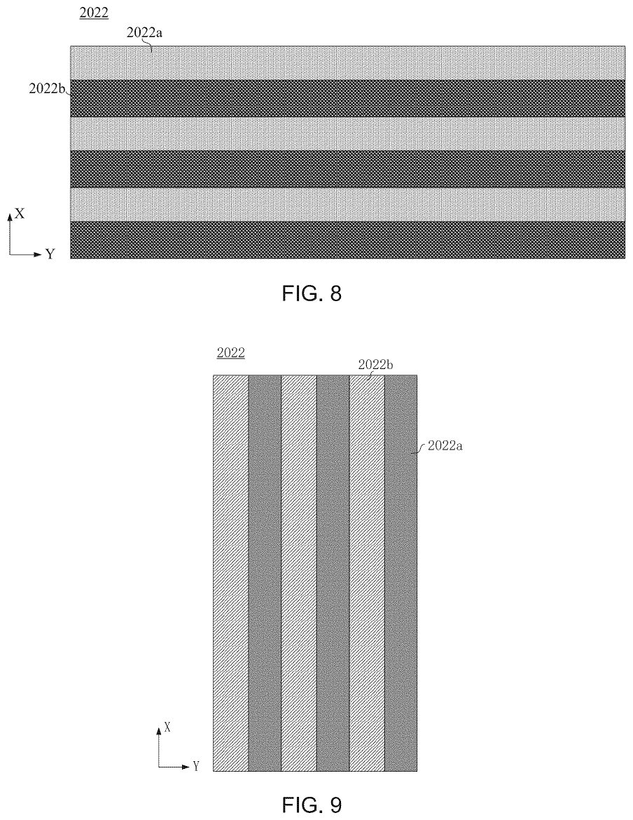

For example, as shown in FIGS. 7A to 7D, the material of the filling portion 2022 includes one of thermally conductive silicone and graphite; alternatively, as shown in FIGS. 8 and 9, the material of the filling portion 2022 includes both thermally conductive silicone and graphite.

In a case where the material of the filling portion 2022 includes both thermally conductive silicone and graphite, the filling portion 2022 includes a thermally conductive silicone layer 2022a and a graphite layer 2022b.

FIG. 8 is a structural diagram of the filling portion 2022. As shown in FIG. 8, a direction perpendicular to the display portion 101 is a third direction X, and the thermally conductive silicone layer 2022a and the graphite layer 2022b may be, for example, arranged in a stacked manner in the third direction X.

FIG. 9 is a structural diagram of the filling portion 2022 in FIG. 3 in a region D in a case where the filling portion 2022 includes both the thermally conductive silicone layer 2022a and the graphite layer 2022b. As shown in FIG. 9, a direction parallel to the display portion 101 is a fourth direction Y, and the thermally conductive silicone layer 2022a and the graphite layer 2022b may be arranged, for example, side by side on a plane where the fourth direction Y is located, and are connected to each other.

It will be noted that FIGS. 8 and 9 both illustrate examples of alternating stacking of groups in a unit of a single thermally conductive silicone layer 2022a and a single graphite layer 2022b, but the stacking mode of the thermally conductive silicone layer(s) 2022a and the graphite layer(s) 2022b in the present disclosure is not limited thereto. For example, groups in a unit of multiple thermally conductive silicone layers 2022a and multiple graphite layers 2022b are alternately stacked, alternatively, one or more graphite layers 2022b are provided between two thermally conductive silicone layers 2022a.

The thickness of the thermally conductive silicone layer 2022a and the thickness of the graphite layer 2022b may be the same, but the thickness setting of the thermally conductive silicone layer 2022a and the graphite layer 2022b in the present disclosure is not limited thereto. For example, there may be a difference in thickness between the thermally conductive silicone layer 2022a and the graphite layer 2022b.

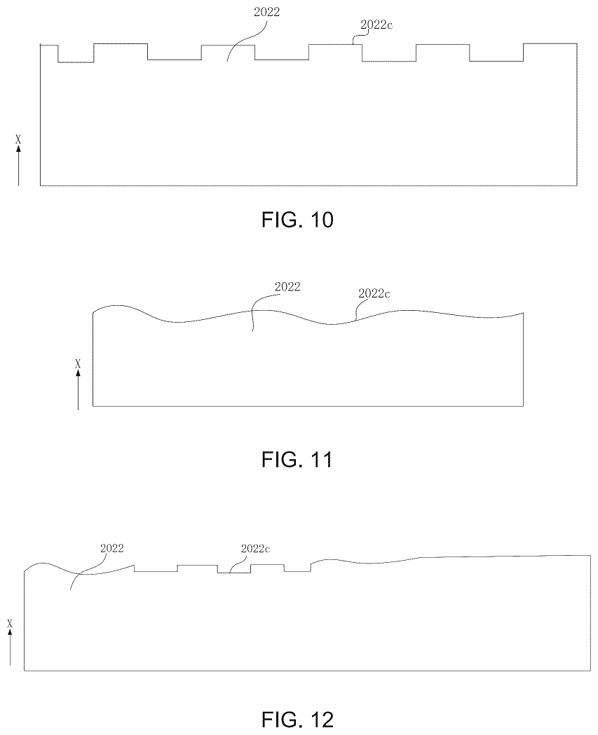

In some embodiments, as shown in FIGS. 10 to 12, a surface of the filling portion 2022 away from the metal layer 201 is a first surface 2022c, and the first surface 2022c has a serrated and/or wavy morphology.

The first surface 2022c is connected to the display portion 101 of the display panel 10. The first surface 2022c is provided to have a serrated and/or wavy morphology, thereby being beneficial to increasing a ratio of an area of the first surface 2022c to an area of the display portion 101, improving the thermal conductivity efficiency, and further avoiding heat accumulation in the peripheral area AN of the display portion 101.

For example, as shown in FIG. 10, a cross section of the first surface 2022c in the third direction X is in a serrated shape. The serrated shape may be, for example, square serration or triangular serration.

As shown in FIG. 11, a cross section of the first surface 2022c in the third direction X may be in a wavy shape.

As shown in FIG. 12, a cross section of the first surface 2022c in the third direction X may be in a serrated shape and a wavy shape that are alternately. The serrated shape may be, for example, square serration or triangular serration.

In some embodiments, as shown in FIG. 17, FIG. 17 is a planar structural diagram of the first film structure 2021 and the filling portion 2022 in accordance with some embodiments. The first direction F1 and the second direction F2 are two directions perpendicular to each other in a coordinate system. With a plane defined by the first direction and the second direction as a reference plane, the reference plane is parallel to the first film layer structure 2021 and the filling portion 2022, and an orthographic projection of a connection interface FF between the first film layer structure 2021 and the filling portion 2022 on the reference plane is a smooth arc surface.

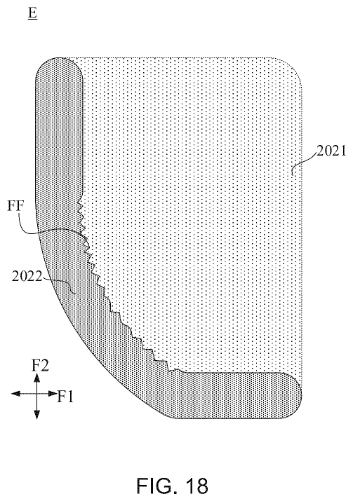

In order to further improve the connection strength between the first film layer structure 2021 and the filling portion 2022 and the stability of the connection interface FF between the first film layer structure 2021 and the filling portion 2022, in some other embodiments, as shown in FIGS. 18 to 20, FIGS. 18 to 20 are each an enlarged schematic diagram of a region E in FIG. 17. An orthographic projection of the connection interface FF between the first film layer structure 2021 and the filling portion 2022 on the reference plane may also be in a serrated or wavy shape, that is, the first film layer structure 2021 and the filling portion 2022 are mutually clamped at the connection interface FF, which is beneficial to improving the stability of the connection interface FF.

For example, as shown in FIG. 18, the orthographic projection of the connection interface FF between the first film layer structure 2021 and the filling portion 2022 on the reference plane is provided in a triangular serrated shape.

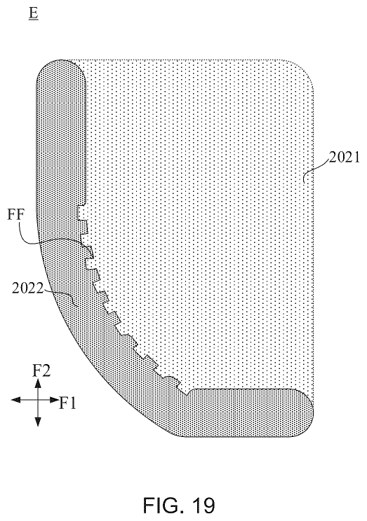

As another example, as shown in FIG. 19, the orthographic projection of the connection interface FF between the first film layer structure 2021 and the filling portion 2022 on the reference plane is provided in a square serrated shape.

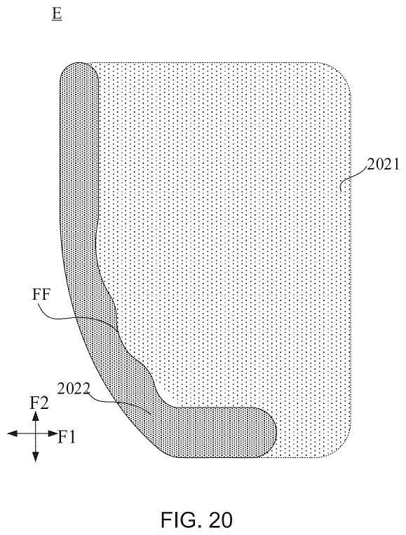

As another example, as shown in FIG. 20, the orthographic projection of the connection interface FF between the first film layer structure 2021 and the filling portion 2022 on the reference plane is provided in a wave shape.

In a case where the heat dissipation film 20 has a rectangular structure, the composite film layer 202 also has the same rectangular structure as the heat dissipation film 20. As shown in FIG. 3, the shape of the composite film layer 202 may be a round-corner rectangular structure in the rectangular structure.

With continuous narrowing of the frame of the display panel 10, an area of the peripheral area AN of the display portion 101 gradually decreases, and areas of the first corner region N1, the second corner region N2, the third corner region N3 and the fourth corner region N4 in the peripheral area AN also gradually decreases. In a case where any one or more of the first corner region N1, the second corner region N2, the third corner region N3 and the fourth corner region N4 are both/all provided with the GOA circuits 32, the connecting lines 33 and the electrostatic protection circuit 31, a region of the GOA circuits 32, the connecting lines 33 and the electrostatic protection circuit 31 is continuously reduced. Under a condition of high brightness of the display panel 10, the heat generated by the GOA circuits 32, the connecting lines 33 and the electrostatic protection circuit 31 increases and is difficult to dissipate, resulting in heat accumulation in the corner region where the GOA circuits 32, the connecting lines 33 and the electrostatic protection circuit 31 are located and temperature increase, and further leading to reduction of lives of light-emitting devices in the display area AA adjacent to the corner region. As a result, the image in the display area AA displays unevenly, thereby affecting the display effect.

Based on this, in some embodiments, as shown in FIG. 3, the filling portion 2022 is at least disposed at a corner of the composite film layer 202. FIG. 3 illustrates an example where the filling portion 2022 is disposed at two corners of the composite film layer 202. Orthographic projections of the above two corners on the display portion 101 overlap with the third corner region N3 and the fourth corner region N4 in the peripheral area AN, so that heat from the third corner region N3 and the fourth corner region N4 in the peripheral area AN may be dissipated to avoid heat accumulation in the regions, which is beneficial to improving the display effect of the display area AA.

For example, the filling portion 2022 may alternatively be disposed at any corner of the composite film layer 202, and an orthographic projection of the corner on the display portion 101 overlaps with one of the first corner region N1, the second corner region N2, the third corner region N3 and the fourth corner region N4 in the peripheral area AN.

The filling portion 2022 may alternatively be disposed at any three corners of the composite film layer 202, and orthographic projections of the above three corners on the display portion 101 overlap with three of the first corner region N1, the second corner region N2, the third corner region N3 and the fourth corner region N4 in the peripheral area AN.

The filling portion 2022 may alternatively be disposed at any four corners of the composite film layer 202, and orthographic projections of the above four corners on the display portion 101 overlap with four of the first corner region N1, the second corner region N2, the third corner region N3 and the fourth corner region N4 in the peripheral area AN. Therefore, corner regions in the peripheral area AN overlapping with the four corners may be dissipated to avoid heat accumulation in the regions, which is beneficial to improving the display effect of the display area AA.

The filling portion 2022 may also be disposed in a partial region of the frame of the composite film layer 202, and an orthographic projection of the region on the display portion 101 overlaps with a partial region of the first frame region M1, the third frame region M3, the second frame region M2 and the fourth frame region M4 in the peripheral area AN.

The filling portion 2022 may also be disposed in all the frame regions and the four corner regions of the composite film layer 202, that is, the filling portion 2022 is in a shape of a rectangular ring surrounding the outside of the first film layer structure 2021, and an orthographic projection of the filling portion 2022 on the display portion 101 overlaps with the peripheral area AN. Therefore, regions in the peripheral area AN that overlaps with the orthographic projection of the filling portion 2022 on the display portion 101 may be dissipated to avoid heat accumulation in the regions, which is beneficial to improving the display effect of the display area AA.

In some embodiments, as shown in FIG. 3, in a case where the filling portion 2022 is disposed at corner(s) of the composite film layer 202, the orthographic projection of the filling portion 2022 on the display portion 101 may be substantially in an arc shape. That is, the shape of the filling portion 2022 is the same as or similar to the shapes of the first corner region N1, the second corner region N2, the third corner region N3, and the fourth corner region N4 in the peripheral area AN.

It will be noted that, the term “substantially in an arc shape” means that a shape of an edge of the orthographic projection of the filling portion 2022 on the display portion 101 is an arc as a whole, but is not limited to a standard arc. That is, the “arc shape” here is a shape similar to an arc. For example, the arc has two straight sides, and the two sides are curved at the intersection position (i.e., the corner), that is, the corner is smooth.

The filling portion 2022 is mainly used to dissipate the heat generated by the peripheral circuits and connecting lines in the peripheral area AN of the display portion 101 during operation. The corresponding relationship between the GOA circuits 32, the connecting lines 33 and the electrostatic protection circuit 31 in the peripheral area AN and the orthographic projection of the filling portion 2022 on the peripheral area AN may be designed as follows.

In some embodiments, the orthographic projection of the filling portion 2022 on the peripheral area AN covers at least part of the GOA circuits, so as to be used to dissipate heat of the GOA circuits in the peripheral area AN.

For example, the orthographic projection of the filling portion 2022 on the peripheral area AN covers part of the GOA circuits or all of the GOA circuits.

In some other embodiments, the orthographic projection of the filling portion 2022 on the display portion 101 may further cover part of or all of the connecting lines 33 to dissipate heat of the connecting lines in the peripheral area AN.

In some other embodiments, the orthographic projection of the filling portion 2022 on the display portion 101 may further cover at least part of the electrostatic protection circuit 31.

For example, the orthographic projection of the filling portion 2022 on the peripheral area AN may cover part of the electrostatic protection circuit 31 or all of the electrostatic protection circuit 31.

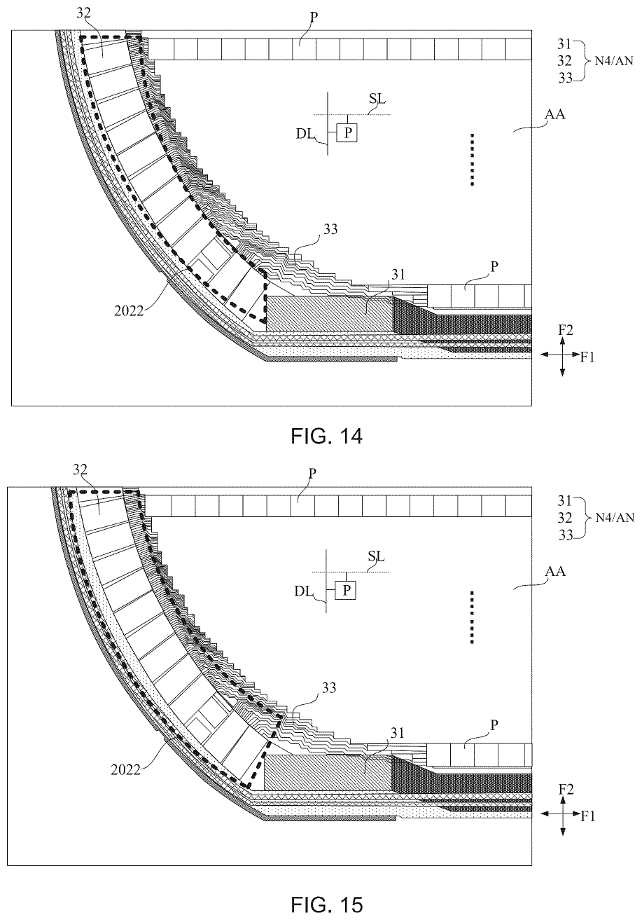

The corresponding relationship between the orthographic projection of the filling portion 2022 on the fourth corner region N4 and the electrostatic protection circuit 31, the GOA circuits 32 and the connecting lines 33 in the fourth corner region N4 will be described below in conjunction with FIGS. 14 to 16 in a case where the filling portion 2022 is provided at a corner of the composite film layer 202 corresponding to the fourth corner region N4 in the peripheral area AN.

It will be noted that for convenience of description of the corresponding relationship between the orthographic projection of the filling portion 2022 on the fourth corner region N4 and the electrostatic protection circuit 31, the GOA circuits 32 and the connecting lines 33 in the fourth corner region N4, transparency treatment is applied to the orthographic projection of the filling portion 2022 on the fourth corner region N4, and for convenience of distinguishing the filling portion 2022 and the fourth corner region N4, a region surrounded by the dotted line in each of FIGS. 14 to 16 is the filling portion 2022 of the composite film layer 202.

In some embodiments, as shown in FIG. 14, the orthographic projection of the filling portion 2022 on the fourth corner region N4 covers at least part of the GOA circuits 32, so as to be used to dissipate heat of the GOA circuits 32 in the fourth corner region N4.

For example, the orthographic projection of the filling portion 2022 on the fourth corner region N4 covers part of the GOA circuits 32 or all of the GOA circuits 32.

In some other embodiments, as shown in FIG. 15, the orthographic projection of the filling portion 2022 on the fourth corner region N4 may further cover part of the connecting lines 33, so as to be used to dissipate heat of the connecting lines 33 in the fourth corner region N4.

It can be understood that the connecting lines 33 are connected to the pixel units P in the display area AA, that is, ends of the connecting lines 33 may be overlapped with the display area AA. In order to avoid damage to the display devices in the pixel units P, the orthographic projection of the filling portion 2022 on the fourth corner region N4 covers part of the connecting lines 33, so that there is a distance d3 between the orthographic projection of the filling portion 2022 and the edge of the display area AA (referring to FIG. 3), and the orthographic projection of the filling portion 2022 does not cover part of the connecting lines 33 proximate to the display area AA, thereby avoiding damage to the display devices in the pixel units P.

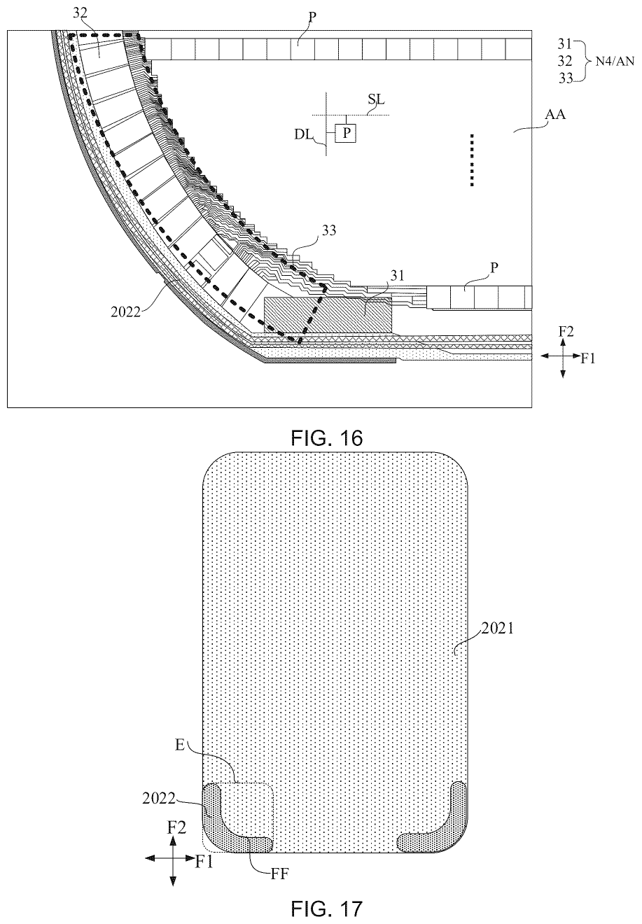

In some other embodiments, as shown in FIG. 16, the orthographic projection of the filling portion 2022 on the fourth corner region N4 may further cover at least part of the electrostatic protection circuit 31, so as to be used to dissipate heat of the electrostatic protection circuit 31 in the fourth corner region N4.

For example, the orthographic projection of the filling portion 2022 on the fourth corner region N4 covers part of the electrostatic protection circuit 31 or all of the electrostatic protection circuit 31.

The foregoing descriptions are merely specific implementations of the present disclosure, but the protection scope of the present disclosure is not limited thereto. Changes or replacements that any person skilled in the art could conceive of within the technical scope of the present disclosure shall be included in the protection scope of the present disclosure. Therefore, the protection scope of the present disclosure shall be subject to the protection scope of the claims.

1. A display module, comprising:
a display panel including a display portion for displaying an image, the display portion including a display area and a peripheral area surrounding the display area; and
a heat dissipation film stacked on a non-display surface of the display portion; the heat dissipation film including a metal layer and a composite film layer that are stacked, and the metal layer being farther away from the display portion than the composite film layer; wherein
the composite film layer includes a first film layer structure and a filling portion, and the first film layer structure and the filling portion are both connected to the metal layer; and
an orthographic projection of the first film layer structure on the display portion at least covers the display area, an orthographic projection of the filling portion on the display portion at least covers part of the peripheral area, and a thermal conductivity of the filling portion is greater than a thermal conductivity of the first film layer structure.

2. The display module according to claim 1, wherein the first film layer structure includes a bonding layer and a foam layer that are stacked, and the foam layer is closer to the metal layer than the bonding layer; and
a material of the filling portion includes at least one of thermally conductive silicone or graphite.

3. The display module according to claim 2, wherein the filling portion includes a thermally conductive silicone layer and a graphite layer; the thermally conductive silicone layer and the graphite layer are stacked in a direction perpendicular to the non-display surface of the display portion, or the thermally conductive silicone layer and the graphite layer are arranged side by side on a plane parallel to the non-display surface of the display portion and are connected to each other.

4. The display module according to claim 1, wherein a surface of the filling portion away from the metal layer has a serrated and/or wavy morphology.

5. The display module according to claim 1, wherein an edge of the first film layer structure has a notch, and the filling portion is disposed in the notch and connected to a side face of the first film layer structure at the notch.

6. The display module according to claim 5, wherein a side face of the first film structure outside the notch and a side face of the filling portion away from the display area are smoothly transitioned.

7. The display module according to claim 1, wherein the composite film layer has a rectangular structure, and the filling portion is at least disposed at a corner of the composite film layer.

8. The display module according to claim 7, wherein the display panel further includes a bending portion and a bonding portion that are disposed on at least one side of the display portion, and the display portion, the bending portion and the bonding portion are sequentially connected; and
the filling portion is disposed at two corners at both ends of a side edge of the composite film layer corresponding to the bending portion and the bonding portion.

9. The display module according to claim 7, wherein the orthographic projection of the filling portion on the display portion is substantially in an arc shape.

10. The display module according to claim 1, wherein the display portion includes a plurality of pixel units disposed in the display area, and a gate driver circuit and a connecting line that are disposed in the peripheral area; the connecting line is located between the gate driver circuit and the display area, and is used to connect the gate driver circuit and the plurality of pixel units; and
the orthographic projection of the filling portion on the display portion covers at least part of the gate driver circuit.

11. The display module according to claim 10, wherein the orthographic projection of the filling portion on the display portion covers at least part of the connecting line, or has no overlap with the connecting line.

12. The display module according to claim 10, wherein the display portion further includes an electrostatic protection circuit disposed in the peripheral area; and
the orthographic projection of the filling portion on the display portion at least covers part of the electrostatic protection circuit.

13. The display module according to claim 1, wherein the orthographic projection of the filling portion on the display portion and the display area have a gap therebetween.

14. The display module according to claim 1, wherein a distance between an edge of the orthographic projection of the filling portion on the display portion away from the display area and an edge of the display portion is in a range of 0 mm to 0.35 mm, inclusive.

15. A heat dissipation film, comprising:
a metal layer; and
a composite film layer stacked on the metal layer; wherein
the composite film layer includes a first film layer structure and a filling portion, the first film layer structure and the filling portion are both connected to the metal layer, and a thermal conductivity of the filling portion is greater than a thermal conductivity of the first film layer structure.

16. The heat dissipation film according to claim 15, wherein the first film layer structure includes a bonding layer and a foam layer that are stacked, and the foam layer is closer to the metal layer than the bonding layer; and
a material of the filling portion includes at least one of thermally conductive silicone or graphite.

17. The heat dissipation film according to claim 15, wherein an edge of the first film layer structure has a notch, and the filling portion is disposed in the notch and connected to a side face of the first film layer structure at the notch.

18. The heat dissipation film according to claim 15, wherein the composite film layer has a rectangular structure, and the filling portion is at least disposed at a corner of the composite film layer, and an orthographic projection of the filling portion on the metal layer is substantially in an arc shape.

19. A display apparatus, comprising:
the display module according to claim 1, wherein the display panel in the display module includes the display portion, a bending portion and a bonding portion that are connected in sequence; the bonding portion is disposed on a side of the non-display surface of the display portion by bending action of the bending portion; and the heat dissipation film in the display module is disposed between the display portion and the bonding portion; and
a back film including a first portion and a second portion; wherein the first portion of the back film is disposed on the non-display surface of the display portion, and is closer to the display portion than the heat dissipation film; and the second portion of the back film is disposed on a side of the bonding portion proximate to the display portion, and is closer to the display portion than the bonding portion.

20. The heat dissipation film according to claim 15, wherein a surface of the filling portion away from the metal layer has a serrated and/or wavy morphology.
